(19) United States
(12) Patent Application Publication
(10) Pub. No.: US 2024/0105475 A1
(43) Pub. Date: Mar. 28, 2024

(54) Method for manufacturing an electronic device and associated transfer device

(71) Applicant: ALEDIA, ÉCHIROLLES (FR)

(72) Inventors: Nohora CAICEDO, Grenoble (FR); Frédéric MAYER, Moirans (FR)

(21) Appl. No.: 18/272,453

(22) PCT Filed: Jan. 25, 2022
(86) PCT No.: PCT/FR2022/050131

§ 371 Date: Jul. 14, 2023

(30) Foreign Application Priority Data
Jan. 29, 2021 (FR) FR2100846

(51) Int. Cl. H01L 21/67; H01L 25/065

(52) U.S. Cl. CPC H01L 21/67144; H01L 25/0655

(57) ABSTRACT

A method for manufacturing an electronic device including a transfer phase a a step E1 of providing a substrate towards a receiving substrate, step E2 of providing a transfer device, a step E3 including adjusting a physical parameter, a set-up step E4, a step E5 including adjusting the physical parameter so that the value of the physical parameter is included within a second range of values, a step E7 including depositing an active element in which the physical parameter allows placing the material in a first state to impart a detachment between the active element and the housing in which the active element has been inserted at step E4, step E7 being carried out so that the detachment causes setting of a portion of the active element in contact with the receiving substrate.

### TECHNICAL FIELD

The present disclosure primarily concerns a method for manufacturing an electronic device including a plurality of active elements, the method including a phase of transferring at least one of said active elements from a primary substrate towards a receiving substrate belonging to the electronic device.

The present disclosure also concerns a transfer device used for the implementation of such a manufacturing method.

One of the applications that are particularly targeted, yet without limitation, concerns the manufacture of optoelectronic devices, in particular luminous display screens, where each active element to be transferred during the manufacture generally comprises at least one light-emitting diode and possibly a control device associated to said at least one light-emitting diode, such as for example a transistor. Nonetheless, it is still possible to consider any other type of application of an electronic device where it is necessary to transfer a plurality of active elements with very small dimensions (typically fragile and delicate to handle because of the potentially nanometric dimensions) from a primary substrate used for the preparation of the active elements before transfer thereof, towards a receiving substrate that is included in the composition of the final electronic device.

### BACKGROUND

In the manufacture of many electronic devices requiring a transfer of active elements with very small dimensions (typically at least micrometric and possibly nanometric) from a primary substrate used for the preparation of active elements before transfer thereof towards a receiving substrate that is included in the composition of the final electronic device, this transfer step represents a real difficulty to overcome efficiently and at a lower cost because of the fragility of the active elements and the difficulty to handle them given their extremely small dimensions.

Besides, this difficulty to overcome increases with the current trend for increasing miniaturization of the manufactured electronic devices.

In particular, in the field of luminous display screens, the luminous active elements that constitute the screen must be arranged in a matrix-like way more and more accurately as the resolution of the screens increases. Each of these luminous active elements comprises at least one light-emitting diode and is organized in the form of a multicolor pixel or in the form of a monochrome sub-pixel.

It is known to have to transfer active elements including one or several light-emitting diode(s), from a primary support serving in the manufacture and/or the preparation of the active elements, towards a receiving support different from the primary support and intended to be included in the constitution of the manufactured electronic device. For example, it is known that the primary substrate is in the form of a wafer based on silicon or sapphire, used for the growth of the light-emitting diodes. Alternatively, the primary substrate may be an intermediate substrate (also known as «grip») to which the active elements are stuck for a complementary treatment and a possible operation to singularize them, before transfer.

Currently, a widespread transfer technique consists in carrying out this transfer using a buffering matrix.

Unfortunately, the buffering matrices cannot be used to properly grasp active elements with a micrometric size or smaller. Moreover, they do not allow placing them over the receiving substrate with a good accuracy and with a high yield. The nature of the material of the buffering matrices also poses problems because it does not withstand temperature rises, which are yet necessary in some processes to detach the active elements off the primary substrate and/or to attach the active elements transferred on the receiving substrate.

### BRIEF SUMMARY

The present disclosure aims at providing a solution for manufacturing an electronic device of the aforementioned type which addresses all or part of the aforementioned problems.

In particular, to the disclosure provides a solution to at least one of the following problems:
obtain an electronic device having active elements accurately arranged, in a robust manner and that being so with high cost and yield, and that being so in particular for active elements having micrometric and possibly nanometric dimensions;
obtain a transfer of the active elements that is compatible with high temperatures, typically allowing carrying out operations of welding, fracture detachment and attachment on the receiving substrate requiring a rise in the temperature or an annealing.

This aim could be achieved thanks to the implementation of a method for manufacturing an electronic device including a plurality of active elements, the method including a transfer phase in which at least one of said active elements is transferred from a primary substrate towards a receiving substrate where the receiving substrate belongs to the manufactured electronic device, the transfer phase comprising the following steps:
a step E1 of providing the primary substrate having a support face on which the at least one active element to be transferred, having a three-dimensional shape, is disposed,
a step E2 of providing a transfer device delimiting a plurality of gripping portions where each gripping portion is intended for gripping of an active element to be transferred and comprises at least one housing opening outwardly through an opening, the housing of each gripping portion being delimited in a material having an ability to occupy a first state when a physical parameter associated to said material takes on a value comprised within a first range of values and a second state when the value taken on by the physical parameter is comprised within a second range of values, the second range of values being separate from the first range of values, said material having a greater ability to deform in the first state than in the second state,
a step E3 comprising adjusting the physical parameter so that the value taken on by the physical parameter is included within the first range of values to place the material in the first state,
a set-up step E4, in which all or part of at least one of the active elements disposed over the support face of the primary substrate is inserted into the housing of one of the gripping portions throughout the opening,
a step E5 comprising adjusting the physical parameter so that the value taken on by the physical parameter is included within the second range of values to place the material in the second state,
a step E6 of transferring the active element towards the receiving substrate resulting from a displacement of the transfer device relative to the primary substrate and to the receiving substrate, in which the value taken on by the physical parameter is kept within the second range of values so as to keep the material in the second state in a way imparting a temporary attachment between the active element and the housing into which the active element has been inserted at step E4,
a step E7 comprising depositing the active element transferred at step E6 over a receiving face of the receiving substrate, in which the physical parameter is adjusted so that the value taken on by the physical parameter is comprised within the first range of values so as to place the material in the first state in a way imparting a detachment between the active element and the housing into which the active element has been inserted at step E4.

Advantageously, the adjustment of the physical parameter during step E3 to place the material in the first state allows making the material more deformable to enable the introduction of a portion of the active element in the housing.

Moreover, and advantageously, the adjustment of the physical parameter during step E5 to place the material in the second state allows holding the active element in the housing by mechanical pressure, for example by concentric lateral pinching on the hooking portion of the active element. Thus, it is possible to implement the transfer phase without requiring any adhesion between the active element and the housing.

Finally, the adjustment of the physical parameter during step E7 to place the material in the first state allows making the material more deformable to enable the release of the active element, for example by gravity, without having to resort to an adhesion force between the active element and the receiving substrate.

In an implementation of the method, at step E7, the physical parameter is adjusted so that the value taken on by the physical parameter is comprised within the first range of values while the active element is at a distance from the receiving face of the receiving substrate.

According to one embodiment, step E7 is carried out so that said detachment causes setting at least one portion of the active element in contact with the receiving face of the receiving substrate.

According to one embodiment, step E7 is carried out so that said detachment enables setting at least one portion of the active element in contact with the receiving face of the receiving substrate.

Hence, it should be understood that step E7 enables the detachment between the active element and the housing so as to enable, whether simultaneously or not, setting at least one portion of the active element in contact with the receiving face of the receiving substrate.

In an implementation of the method, at step E7, the physical parameter is adjusted so that the value taken on by the physical parameter is comprised within the first range of values while the active element is in contact with the receiving face of the receiving substrate.

In an implementation of the method, at step E1, each active element is held through a fastening element arranged between the active element and the primary substrate and exerting a fastening force holding the active element on the support face of the primary substrate, and wherein at step E6, the transfer device exerts a pulling force on the active element directed on the side opposite to the primary substrate and having an intensity higher than said fastening force.

In an implementation of the method, the physical parameter is a temperature taken on by the material in which the housing is delimited.

In an implementation of the method, one amongst the first range of values and the second range of values is comprised between 50° C. and 400° C.

In an implementation of the method, one amongst the first range of values and the second range of values is comprised between 0° C. and 40° C.

In an implementation of the method, the first range of values is delimited by a first temperature lower bound and by a second temperature upper bound and the second range of values is delimited by a second temperature lower bound and by a second temperature upper bound, wherein the first temperature lower bound is strictly higher than the second temperature upper bound, and whereon the switch from step E3 into step D5 comprises a decrease of the temperature taken on by the material in which the housing is delimited and the switch from step E5 into step E7 comprises an increase of the temperature taken on by the material in which the housing is delimited.

In an implementation of the method, the first range of values is delimited by a first temperature lower bound and by a first temperature upper bound and the second range of values is delimited by a second temperature lower bound and by a second temperature upper bound, wherein the second temperature lower bound is strictly higher than the first temperature upper bound, and wherein the switch from step E3 into step E5 comprises an increase of the temperature taken on by the material in which the housing is delimited and the switch from step E5 into step E7 comprises a decrease of the temperature taken on by the material in which the housing is delimited.

In an implementation of the method, during step D4, the material in which the housing is delimited is shaped, under the effect of the insertion of the active element into the housing, so as to adopt a three-dimensional configuration having a shape complementary to all or part of the external shape of the active element.

In an implementation of the method, during step E4, a hooking portion delimited by a lateral face of the active element to be transferred is inserted through the opening until being surrounded by the housing and being axially retained by a shoulder that is delimited by the gripping portion at the periphery of the opening and which extends, after step E4, between the hooking portion of the active element and the primary substrate.

In an implementation of the method, the shoulder is created by a deformation of the material in which the housing is delimited and/or is inserted into the interval between the hooking portion of the active element and the primary substrate under the effect of a compressive force applied to said material between the transfer device and the support face of the primary support.

In an implementation of the method, the material in which the housing is formed is a polymer and/or a thermoplastic.

In an implementation of the method, at least one of the gripping portions of the transfer device comprises a barrier layer having an anti-stick action between all or part of said gripping portion and all or part of the active element set in place at step E4, the barrier layer being disposed between the active element transferred at step E6 and the material in which the housing is delimited.

In an implementation of the method, the at least one active element transferred towards the receiving substrate includes an active portion adapted to change state when a control parameter external to said active portion is applied to said active portion.

In an implementation of the method, the active portion of the at least one active element transferred by the transfer device comprises a light-emitting diode and wherein the active element includes a control device adapted to act on at least one parameter associated to the light-emitting diode.

In an implementation of the method, step E7 comprises the application of a connection setting force on the active element by the gripping portion of the transfer device, the connection setting force being directed towards the receiving substrate.

In an implementation of the method, the at least one active element transferred by the transfer device comprises at least one electrode and the electronic device to be manufactured comprises a connection element arranged at least at the level of the contact between the active element and the receiving substrate which belongs to the electronic device;

the connection element comprising an electrically-insulating material embedding a set of metallic particles, and being adapted to vary between a first electrical insulation state when the connection element is not subjected to the connection setting force, and a second directional electrical conductivity state in which most of the metallic particles are in electrical contact under the effect of the connection setting force.

The disclosure also covers a transfer device allowing transferring three-dimensional shaped active elements for an electronic device, the transfer device delimiting a plurality of gripping portions where each gripping portion is intended for gripping of an active element to be transferred and comprises at least one housing opening outwardly through an opening, the housing of each gripping portion being delimited in a material having an ability to occupy a first state when a physical parameter associated to said material takes on a value comprised within a first range of values and a second state when the value taken on by the physical parameter is comprised within a second range of values, the second range of values being separate from the first range of values, said material having a greater ability to deform in the first state than in the second state;

the transfer device being adapted to be used in such a manufacturing method to transfer at least one of said active elements towards a receiving substrate belonging to the electronic device from a primary substrate having a support face on which the least one active element to be transferred is disposed.

### BRIEF DESCRIPTION OF THE DRAWINGS

Other aspects, aims advantages and features of the disclosure will appear better upon reading the following detailed description of preferred embodiments thereof, provided as a non-limiting example, and made with reference to the appended drawings wherein:

FIG. 1 is a schematic sectional view of an example of a manufacturing method according to the disclosure wherein an active element is transferred from a primary substrate into a receiving substrate of the electronic device.

FIG. 2 is a schematic view of an example of a manufacturing method according to the disclosure wherein several active elements are transferred from a primary substrate into a receiving substrate of the electronic device.

### DETAILED DESCRIPTION

In the figures and in the following description, the same reference numerals represent identical or similar elements. In addition, the different elements are not represented to scale in order to promote clarity of the figures.

Moreover, the different embodiments and variants do not exclude each other and could, on the contrary, be combined together.

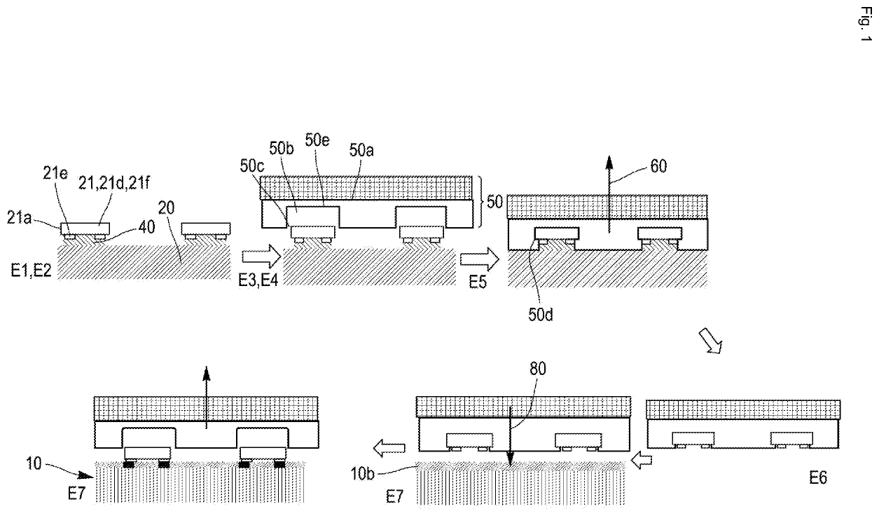

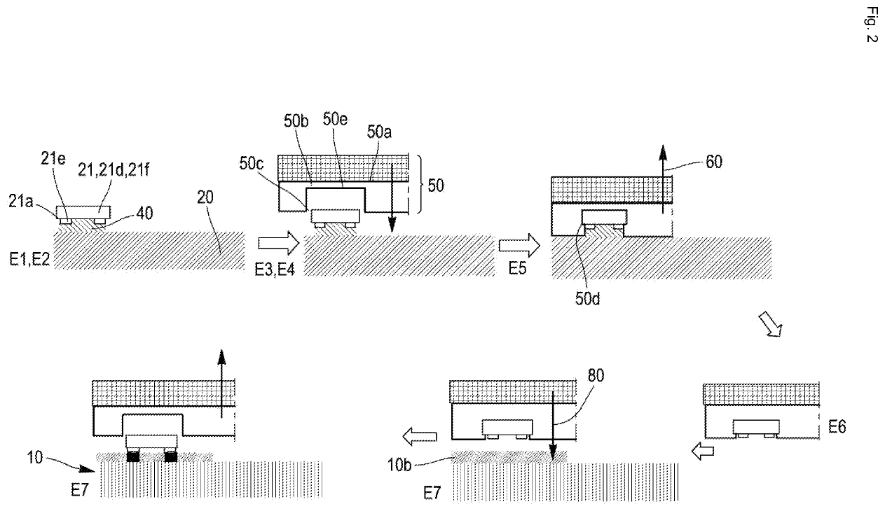

As illustrated in FIGS. 1 and 2, the disclosure primarily concerns a method for manufacturing an electronic device 10 including a plurality of active elements 21.

The manufacturing method includes a transfer phase in which at least one of these active elements 21 is transferred from an initial primary substrate 20 having served in the manufacture thereof, towards a receiving substrate such that this receiving substrate belongs to the electronic device 10 obtained through the implementation of the manufacturing method. Each active element 21 to be transferred has a three-dimensional shape, by having two components when viewed in the plane of the primary substrate and one component when viewed in a direction transverse to this plane.

Each active element 21 may comprise a light-emitting element comprising at least one light-emitting diode. Said at least one light-emitting diode may be of the wired, or conical, or frustoconical, type, and be adapted to emit and/or capture light. Preferably, each has micrometric, and possibly nanometric, dimensions and has a main axis of extension. Each light-emitting diode may also be of the two-dimensional type with a micrometric height. In one example, at least two light-emitting diodes of at least one of the active elements 21 are adapted to emit at least two light radiations having different wavelengths. In another example, at least one of the light-emitting diodes of at least one of the active elements 21 is surrounded at least partially by photoluminescent materials adapted to transform the light radiation emitted by the corresponding light-emitting diode. Each light-emitting diode may comprise a first portion doped according to a first doping type for example of the N type, a second portion doped according to a second doping type for example of the P type, and an active portion adapted to change state when an external parameter external to the active portion is applied to the active portion. For example, it comprisescomprises the application of a current or of a potential difference between the doped portions.

Each active element 21 to be transferred possibly comprise a control device 21f associated to said at least one light-emitting diode, such as for example a transistor. Thus, the control device 21f may comprise at least one transistor of the CMOS technology and/or bipolar and/or of the thin film transistor (TFT) type or any other technology such as GaN (a mixture of Gallium and Nitrogen) or GaN over silicon. It may also include memories or passive components. Once arranged over the receiving substrate, it may for example be powered with a voltage or a current originating from possible conductive elements arranged over the receiving substrate of the electronic device 1. In particular, the control device 21f is adapted to act on at least one parameter associated to the active portion. In one example, the control device 21f ensures a modulation of at least one emission parameter related to the light radiation that might be emitted by the active portion of the at least one light-emitting diode arranged in the active element 21.

For example, an emission parameter may be the light intensity, the light emission angle or the color of the emitted light.

The active elements 21 may be in electrical contact with at least one electrode 21e intended to cooperate, upon completion of the manufacturing method, with an interconnection interface disposed at a surface of the electronic device 10.

Upon completion of the manufacturing method, the electronic device 10 preferably comprises a matrix layout of the transferred active elements 21.

According to a non-limiting variant, the active elements 21 may have dimensions comprised between 1 micrometer and 1 millimeter. Yet, these dimensions still could be in the range of a few hundreds of nanometers. Moreover, upon completion of the manufacturing method, the distance separating the active elements 21 on the receiving substrate of the electronic device 10 is, for example, comprised between 1 micrometer and 2 millimeters.

For example, the receiving substrate of the electronic device 10 is electrically-insulating and formed by at least one glass plate. It may also be electrically-conductive and formed by at least one metallic plate for example. The receiving substrate of the electronic device 10 may also comprise electrically-conductive tracks insulated from each other and formed at the surface or inside the receiving substrate of the electronic device 10. The receiving substrate of the electronic device 10 may be formed in a crystalline or non-crystalline material and may also comprise active or passive components, such as transistors or memories. For example, the receiving substrate of the electronic device 10 may constitute a support for a luminous display screen.

As illustrated in FIGS. 1 and 2, the receiving substrate of the electronic device 10 may comprise, in one example, a connection element 10b arranged at least at the level of the contact between each active element 21 and the electronic device 10. The nature of the connection element 10b is not restrictive per se and a person skilled in the art could adapt it based on his general knowledge.

According to an embodiment that is non-limiting yet advantageous in terms of efficiency and simplicity, the connection element 10b may comprise an electrically-insulating material embedding a set of metallic particles, and being adapted to vary between a first electrical insulation state when the connection element 10b is not subjected to a connection setting force 80, and a second directional electrical conductivity state in which most of the metallic particles are in electrical contact under the effect of a connection setting force 80. An example of such a material is an anisotropic conductive film or «ACF». An advantage of this technique is that the contact is formed only beneath the active element 21 without any prior accurate lateral alignment. This avoids that parasitic welds bring lateral walls of the active elements 21 in contact and create short-circuits. In another example, the connection element 10b is constituted by at least one Indium pad. Afterwards, each electrode 21e is aligned on these Indium pads in order to achieve an electrical connection.

The connection element 10b allows connecting conductors located at the surface of the receiving substrate with the electrode 21e associated to at least one of the active elements 21 with the application of a pressure on the connection element 10b and at the level of the electrode 21e to be connected. Such a pressure may be obtained through the application of the connection setting force 80 that will be described later on.

The transfer phase primarily comprises a step E1 of providing the primary substrate 20. The primary substrate 20 has a support face on which at least one three-dimensional active element 21 to be transferred is disposed.

In a non-limiting embodiment, each active element 21 is held through a fastening element 40 arranged between the active element 21 and the primary substrate 20. The fastening element 40 exerts a fastening force holding the active element 21 on the support face of the primary substrate 20. For example, the fastening element 40 may be a glue that is sensitive, or not, to an external parameter. In one example, the fastening element 40 may change state according to the temperature or be destroyed by means of a laser (for a «Lift Off» Laser type operation). As example, the fastening element 40 may be formed by a HD3007 polymer, which is a thermoplastic having the capability of being destroyed by means of an infrared laser. Nonetheless, it is still possible that each active element is simply set over the primary substrate 20, without holding by a fastening force.

The transfer phase also comprises a step E2 of providing a transfer device 50 delimiting a plurality of gripping portions 50a where each gripping portion 50a is intended for gripping of an active element 21 to be transferred and comprises at least one housing 50b opening outwardly through an opening 50c. Hence, the housing 50b is blind by means of a bottom on the side opposite to the opening 50c. Lateral walls of the housing 50b extend from this bottom up to the opening 50c.

According to an important aspect, the housing 50b of each gripping portion 50a is delimited in a material having an ability to occupy a first state when a physical parameter associated to this material takes on a value comprised within a first range of values and a second state when the value taken on by the physical parameter is comprised within a second range of values. The second range of values is separate from the first range of values, without any overlapping of the ranges of values. Importantly, the material in which the housing 50b of each gripping portion 50a is delimited has a greater ability to deform in the first state than in the second state.

The material in which the housing 50b of each gripping portion 50a is delimited may be a polymer and/or a thermoplastic and the physical parameter associated to this material is a temperature taken on by the material in which the housing 50b is delimited.

It goes without saying that one way of making the temperature of the material vary comprises making the external temperature of the environment in which the transfer device 50 is located vary adequately, and that being so also according to the duration during which this external temperature is applied.

An example of a material is the polyimide such as PI26-10 or 26-11 or else HD 3007/3008. These materials have the advantage of being compatible with annealing temperatures, for example to perform welds.

In a first variant, the material in which the housing 50b is formed may be present only locally at the level of each housing 50b. In another variant, the transfer device 50 comprises a block formed in this material and the different gripping portions 50a are then integrated in this block.

Afterwards, the transfer phase comprises a step E3 comprising adjusting the physical parameter so that the value taken on by the physical parameter is included in the first range of values to place the material in the first state.

After step E3, the transfer phase comprises a set-up step E4, in which all or part of at least one of the active elements 21 disposed over the support face of the primary substrate 20 is inserted into the housing 50b of one of the gripping portions 50a throughout the opening 50c. Thus, and advantageously, the adjustment of the physical parameter during step E3 to place the material in the first state allows making the material more deformable to enable the introduction of a portion of the active element 21 into the housing 50b.

In this step E4, the opening 50c is firstly placed opposite the active element 21 to be transferred with an alignment for example adjusted within 0.5 micrometers and with an angle adjusted within 15°. Then, the gripping portion 50a and/or the primary substrate 20 is set in motion in a terrestrial reference frame so that at least one portion of the active element 21 penetrates into the housing 50b throughout the opening 50c.

According to one embodiment, during step E4, the material in which the housing 50b is delimited is shaped under the effect of the insertion of the active element 21 into the housing 50b so as to adopt a three-dimensional configuration having a shape complementary to all or part of the external shape of the active element 21. In particular, this shaping of the material is possible because of the implementation of step E3 and of holding thereof during step E4.

According to one embodiment, during step E4, a hooking portion 21a delimited by a lateral face of the active element 21 to be transferred is inserted through the opening 50c until being surrounded by the housing 50b and being axially retained by a shoulder 50d that is delimited by the gripping portion 50a at the periphery of the opening 50c and which extends, at least after step E4 and during the subsequent transfer, between the hooking portion 21a of the active element 21 and the primary substrate 20.

The hooking portion 21a of the active element 21 may comprise, as illustrated in FIGS. 1 and 2, of a detachment extending outwardly from the active element 21 and which will serve as a longitudinal support to take up a pulling force mentioned later on, for unhooking of the active element 21 off to the active element 40. However, a frictional area may also constitute the hooking portion 21a, the housing 50b then exerting a concentric lateral pinching on the hooking portion 21a of the active element 21. The presence of the shoulder 50d is then optional.

Afterwards, the transfer phase comprises, after step E4, a step E5 comprising adjusting the physical parameter so that the value taken on by the physical parameter is included within the second range of values to place the material in the second state. Because of step E5, the material in which the housing 50b of each gripping portion 50a is delimited has, after the set-up of the active element in the corresponding gripping portion 50a that results from step E4, a much reduced ability to deform and even no ability at all. This results in that upon completion of step E5, the active element 21 set in place beforehand has a much reduced possibility, and even no possibility at all in case of presence of the shoulder 50d stiffened in this manner by step E5, to come out of the gripping portion 50a accommodating it, and that being so as long as the value taken on by the physical parameter of the material in which the housing 50b is delimited remains within the second range of values. This is particularly advantageous in the context of transfer up to the receiving substrate. Indeed, the adjustment of the physical parameter during step E5 to place the material in the second state allows holding the active element 21 in the housing 50b by mechanical pressure, for example by concentric lateral pinching on the hooking portion 21a of the active element 21. Thus, it is possible to implement the transfer phase without requiring any adhesion between the active element 21 and the housing 50b.

According to an embodiment presented in the figures, the shoulder 50d is created by a deformation of the material in which the housing 50b is delimited and/or is inserted into the interval between the hooking portion 21a of the active element 21 and the primary substrate 20 under the effect of a compressive force applied to this material between the transfer device 50 and the support face of the primary substrate 20. This deformation of the material allowing creating the shoulder 50d and/or enabling the penetration thereof into the interval between the hooking portion 21a of the active element 21 and the primary substrate 20 is in particular the result of the implementation of step E3 and of holding thereof during step E4.

The transfer phase comprises, after step E5, a step E6 of transferring the active element 21 towards the receiving substrate. This transfer results from a displacement of the transfer device 50 relative to the primary substrate 20 and to the receiving substrate. This could be obtained through a displacement of the transfer device 50 and/or of the primary substrate 20 and/or of the receiving substrate in the terrestrial reference frame. During step E6, the value taken on by the physical parameter associated to the material in which the housing 50b is delimited is kept in the second range of values so as to keep this material in the second state in a way imparting a temporary attachment between the active element 21 and the housing 50b into which the active element 21 has been inserted at step E4, whereas the gripping portion 50a is displaced relative to the primary substrate 20.

According to one implementation, the shoulder 50d that is delimited by the gripping portion 50a at the periphery of the opening 50c extends beneath the hooking portion 21a of the active element 21 throughout the entirety of step E6.

In the aforementioned example where each active element 21 is held through a fastening element 40 arranged between the active element 21 and the primary substrate 20, step E6 comprises an unhooking step in which the transfer device 50 exerts a pulling force 60 on the active element (21) directed on the side opposite to the primary substrate 20 and having an intensity higher than the fastening force ensured by the fastening element 40.

Afterwards, the transfer phase comprises a step E7 comprising depositing the active element 21 transferred at step E6 over a receiving face of the receiving substrate. During this step E7, the physical parameter associated to the material in which each housing 50b is delimited is adjusted so that the value taken on by this physical parameter is comprised in the first range of values, in a manner allowing placing the material in the first state and imparting a detachment between the active element 21 and the housing 50b in which the active element 21 has been inserted at step E4. In other words, the housing 50b recovers its ability to deform and that allows releasing the active element 21 that has been held therein during step E6. During step E7, this detachment could cause setting of at least one portion of the active element 21 in contact with the receiving face of the receiving substrate, either by gravity, or using a guide force, with the receiving face of the receiving substrate. The contact may be a physical contact or an electrical contact with a conductive portion or a connection pad of the receiving substrate of the electronic device 10. Thus, advantageously, the adjustment of the physical parameter during step E7 to place the material in the first state allows making the material more deformable to enable the release of the active element 21, for example by gravity, without having to resort to an adhesion force between the active element 21 and the receiving substrate.

According to a first embodiment, at step E7, the physical parameter is adjusted so that the value taken on by the physical parameter is comprised within the first range of values while the active element 21 is at a distance from the receiving face of the receiving substrate. In this case, the physical, and possibly electrical, contact between the active element 21 and the receiving face of the receiving substrate results from a displacement of the active element 21 after it has been released by the gripping portion 50a, this displacement could, in turn, be induced simply by gravity or by the aforementioned guide force (by magnetic field or by electric field).

Alternatively, in another implementation, at step E7, the physical parameter is adjusted so that the value taken by the physical parameter is comprised within the first range of values while the active element 21 is in physical, and possibly electrical, contact with the receiving face of the receiving substrate.

According to one embodiment, step E7 is carried out so that said detachment enables setting at least one portion of the active element 21 in contact with the receiving face of the receiving substrate.

Hence, it should be understood that step E7 enables the detachment between the active element 21 and the housing 50b so as to enable, whether simultaneously or not, setting of at least one portion of the active element 21 in contact with the receiving face of the receiving substrate.

The first range of values is delimited by a first temperature lower bound and by a first temperature upper bound. The second range of values is delimited by a second temperature lower bound and by a second temperature upper bound.

In a preferred embodiment, the first temperature lower bound is strictly higher than the second temperature upper bound. The switch from step E3 into step E5 comprises a decrease of the temperature taken on by the material in which the housing 50b is delimited and the switch from step E5 into step E7 comprises an increase of the temperature taken on by the material in which the housing 50b is delimited.

In one variant, the second temperature lower bound is strictly higher than the first temperature upper bound. The switch from step E3 into step E5 then comprises an increase of the temperature taken on by the material in which the housing 50b is delimited and the switch from step E5 into step E7 comprises a decrease of the temperature taken on by the material in which the housing 50b is delimited.

As example, the first range of values or the second range of values of the physical parameter is comprised between 50° C. and 400° C.

In the case where the first range of values is comprised between 50° C. and 400° C., it may be provided in particular for the switch from step E3 into step E5 to comprise a decrease of the temperature taken on by the material in which the housing 50b is delimited until reaching a value comprised within the second range of values, for example comprised between 0° C. and 40° C., then the switch from step E5 into step E7 then comprises an increase of the temperature of the material in which the housing 50b is formed until reaching a value comprised between 50° C. and 400° C.

In the case where the second range of values is comprised between 50° C. and 400° C., it may be provided in particular for the switch from step E3 into step E5 to comprise an increase of the temperature taken on by the material in which the housing 50b is delimited until reaching a value comprised between 50° C. and 400° C., then the switch from step E5 into step E7 then comprises a decrease of the temperature of the material in which the housing 50b is formed until reaching a value comprised within the first range of values, for example comprised between 0° C. and 40° C.

Whether in a combined manner or not, the first range of values or the second range of values is comprised between 0° C. and 40° C.

In the case where the second range of values is comprised between 0° C. and 40° C., it may be provided in particular for the switch from step E3 into step E5 to comprise a decrease of the temperature taken on by the material in which the housing 50b is delimited until reaching a value comprised between 0° C. and 40° C., then the switch from step E5 into step E7 then comprises an increase of the temperature of the material in which the housing 50b is formed until reaching a value comprised within the first range of values, for example comprised between 50° C. and 400° C.

In the case where the first range of values is comprised between 0° C. and 40° C., it may be provided in particular for the switch from step E3 into step E5 to comprise an increase of the temperature taken on by the material in which the housing 50b is delimited until reaching a value comprised within the second range of values, for example comprised between 50° C. and 400° C., then the switch from step E5 into step E7 then comprises a decrease of the temperature of the material in which the housing 50b is formed until reaching a value comprised between 0° C. and 40° C.

According to a non-limiting embodiment, the passage of the material from the second state into the first state is accompanied with a phenomenon of expansion of the material, whereas the passage of the material from the first state into the second state is accompanied with a phenomenon of contraction of the material. In this variant, not only the material evolves in terms of hardness/softness when changing state, but concomitantly the material evolves in terms of contraction/expansion. The expansion could facilitate, where necessary, the implementation of steps E3, E4, E7, whereas the contraction could promote the holding necessary for the implementation of step E6. Nonetheless, this contraction/expansion phenomenon remains optional.

Alternatively to the foregoing, the physical parameter associated to the material in which each housing 50b is delimited comprises an electrical voltage to which the material is subjected. For example, the material in which each housing 50b is delimited may be a piezoelectric-type one and the physical parameter may comprise an electrical potential difference causing a reverse piezoelectric effect. As example, the first range of values associated to this physical parameter is preferably comprised between 0V and 0.1V and the second range of values associated to this physical parameter is comprised between 40V and 100V. In particular, the value of these different bounds may depend on the nature of the material and its thickness and a person skilled in the art can determine them based on his general knowledge, through experiments and/or numerical simulations.

In a particular implementation of the manufacturing method, step E7 comprises the application of a connection setting force 80 (which has already been mentioned before with regards to the connection element 10b) on the active element 21 by the gripping portion 50a of the transfer device 50, the connection setting force being directed towards the receiving substrate. For example, this allows forming an electrical connection located between an electrode 21e associated to the active element 21 and a conductive portion of the receiving substrate if a connection element 10b, as described hereinbefore, is formed beforehand over the surface of the receiving substrate.

An advantage of this manufacturing method comprises that the implementation thereof could be carried out with techniques that do not require high temperature and pressure. These techniques are also suited for applications on large surfaces, for example larger than that of an off-the-shelf silicon disk. This is advantageous to make luminous display devices with large dimensions.

This manufacturing method has also the advantage of limiting the number of steps necessary for a transfer of active elements from one substrate to another. In addition, it allows collecting micrometric, and possibly nanometric, active elements 21, to accurately place them over a receiving substrate. The transfer device 50 also allows for production gains.

In a particular implementation of the manufacturing method, at least one of the gripping portions 50a of the transfer device 50 comprises a barrier layer 50e having an anti-stick action between all or part of said gripping portion 50a and all or part of the active element 21 set in place at step E4, the barrier layer 50e being disposed, as illustrated in FIG. 1 or 2, between the active element 21 transferred at step E6 and the material in which the housing 50b is delimited. Thus, this barrier layer 50e limits a hooking by sticking between the gripping portion 50a and the active element 21.

For example, this barrier layer 50e may be formed in a SiO₂ or titanium type material. It may also allow accentuating the gripping power of the housing 50b when the active element 21 is set in place by insertion, at least partial, into the housing in accordance with step E4.

This barrier layer 50e also allows holding the material of the housing 50b and the gripping portion 50a in place while avoiding any displacement or any flexing during the state changes of the material between the first state and the second state.

The disclosure also covers a transfer device 50 for transferring three-dimensional shaped active elements 21 from the primary substrate 20 into the receiving substrate of the electronic device 10. As described hereinbefore, the transfer device 50 delimits a plurality of gripping portions 50a where each gripping portion 50a is intended for gripping of an active element 21 to be transferred and comprises at least one housing 50b opening outwardly through an opening 50c. It has already been mentioned that the housing 50b of each gripping portion 50a is delimited in a material having an ability to occupy a first state when a physical parameter associated to said material takes on a value comprised within a first range of values and a second state when the value taken on by the physical parameter is comprised within a second range of values, the second range of values being separate from the first range of values, said material having a greater ability to deform in the first state than in the second state.

The transfer device 50 is used throughout the steps of the manufacturing method described hereinbefore to transfer at least one of the active elements 21 towards a receiving substrate belonging to the electronic device 10 from a primary substrate 20 having a support face over which the at least one active element 21 to be transferred is disposed.

1. A method for manufacturing an electronic device including a plurality of active elements, the method including a transfer phase in which at least one of said active elements is transferred from a primary substrate towards a receiving substrate where the receiving substrate belongs to the manufactured electronic device, the transfer phase comprising the following steps:
a step E1 of providing the primary substrate having a support face on which the at least one active element to be transferred, having a three-dimensional shape, is disposed,
a step E2 of providing a transfer device delimiting a plurality of gripping portions where each gripping portion is intended for gripping of an active element to be transferred and comprises at least one housing opening outwardly through an opening, the housing of each gripping portion being delimited in a material having an ability to occupy a first state when a physical parameter associated to said material takes on a value comprised within a first range of values and a second state when the value taken on by the physical parameter is comprised within a second range of values, the second range of values being separate from the first range of values, said material having a greater ability to deform in the first state than in the second state,
a step E3 comprising adjusting the physical parameter so that the value taken on by the physical parameter is included within the first range of values to place the material in the first state,
a set-up step E4, in which all or part of at least one of the active elements disposed over the support face of the primary substrate is inserted into the housing of one of the gripping portions throughout the opening,
a step E5 comprising adjusting the physical parameter so that the value taken on by the physical parameter is included within the second range of values to place the material in the second state,
a step E6 of transferring the active element towards the receiving substrate resulting from a displacement of the transfer device relative to the primary substrate and to the receiving substrate, in which the value taken on by the physical parameter is kept within the second range of values so as to keep the material in the second state in a way imparting a temporary attachment between the active element and the housing into which the active element has been inserted at step E4,
a step E7 comprising depositing the active element transferred at step E6 over a receiving face of the receiving substrate, in which the physical parameter is adjusted so that the value taken on by the physical parameter is comprised within the first range of values so as to place the material in the first state in a way imparting a detachment between the active element and the housing into which the active element has been inserted at step E4.

2. The manufacturing method according to claim 1, wherein at step E7, the physical parameter is adjusted so that the value taken on by the physical parameter is comprised within the first range of values while the active element is at a distance from the receiving face of the receiving substrate.

3. The manufacturing method according to claim 1, wherein at step E7, the physical parameter is adjusted so that the value taken on by the physical parameter is comprised within the first range of values while the active element is in contact with the receiving face of the receiving substrate.

4. The manufacturing method according to claim 1, wherein at step E1, each active element is held through a fastening element arranged between the active element and the primary substrate and exerting a fastening force holding the active element on the support face of the primary substrate, and wherein at step E6, the transfer device exerts a pulling force on the active element directed on the side opposite to the primary substrate and having an intensity higher than said fastening force.

5. The manufacturing method according to claim 1, wherein the physical parameter is a temperature taken on by the material in which the housing is delimited.

6. The manufacturing method according to claim 5, wherein one amongst the first range of values and the second range of values is comprised between 50° C. and 400° C.

7. The manufacturing method according to claim 5, wherein one amongst the first range of values and the second range of values is comprised between 0° C. and 40° C.

8. The manufacturing method according to claim 5, wherein the first range of values is delimited by a first temperature lower bound and by a second temperature upper bound and the second range of values is delimited by a second temperature lower bound and by a second temperature upper bound, wherein the first temperature lower bound is strictly higher than the second temperature upper bound, and whereon the switch from step E3 into step D5 comprises a decrease of the temperature taken on by the material in which the housing is delimited and the switch from step E5 into step E7 comprises an increase of the temperature taken on by the material in which the housing is delimited.

9. The manufacturing method according to claim 5, wherein the first range of values is delimited by a first temperature lower bound and by a first temperature upper bound and the second range of values is delimited by a second temperature lower bound and by a second temperature upper bound, wherein the second temperature lower bound is strictly higher than the first temperature upper bound, and wherein the switch from step E3 into step E5 comprises an increase of the temperature taken on by the material in which the housing is delimited and the switch from step E5 into step E7 comprises a decrease of the temperature taken on by the material in which the housing is delimited.

10. The manufacturing method according to claim 1, wherein during step D4, the material in which the housing is delimited is shaped, under the effect of the insertion of the active element into the housing, so as to adopt a three-dimensional configuration having a shape complementary to all or part of the external shape of the active element.

11. The manufacturing method according to claim 1, wherein during step E4, a hooking portion delimited by a lateral face of the active element to be transferred is inserted through the opening until being surrounded by the housing and being axially retained by a shoulder that is delimited by the gripping portion at the periphery of the opening and which extends, after step E4, between the hooking portion of the active element and the primary substrate.

12. The manufacturing method according to claim 10, wherein the shoulder is created by a deformation of the material in which the housing is delimited and/or is inserted into the interval between the hooking portion of the active element and the primary substrate under the effect of a compressive force applied to said material between the transfer device.

13. The manufacturing method according to claim 1, wherein the material in which the housing is formed is a polymer and/or a thermoplastic.

14. The manufacturing method according to claim 1, wherein at least one of the gripping portions of the transfer device comprises a barrier layer having an anti-stick action between all or part of said gripping portion and all or part of the active element set in place at step E4, the barrier layer being disposed between the active element transferred at step E6 and the material in which the housing is delimited.

15. The manufacturing method according to claim 1, wherein the at least one active element transferred towards the receiving substrate includes an active portion adapted to change state when a control parameter external to said active portion is applied to said active portion.

16. The manufacturing method according to claim 15, wherein the active portion of the at least one active element transferred by the transfer device comprises a light-emitting diode and wherein the active element includes a control device adapted to act on at least one parameter associated to the light-emitting diode.

17. The manufacturing method according to claim 1, wherein step E7 comprises the application of a connection setting force on the active element by the gripping portion of the transfer device, the connection setting force being directed towards the receiving substrate.

18. The manufacturing method according to claim 17, wherein the at least one active element transferred by the transfer device comprises at least one electrode and the electronic device to be manufactured comprises a connection element arranged at least at the level of the contact between the active element and the receiving substrate which belongs to the electronic device;
the connection element comprising an electrically-insulating material embedding a set of metallic particles, and being adapted to vary between a first electrical insulation state when the connection element is not subjected to the connection setting force, and a second directional electrical conductivity state in which most of the metallic particles are in electrical contact under the effect of the connection setting force.

19. A transfer device allowing transferring three-dimensional shaped active elements for an electronic device, the transfer device delimiting a plurality of gripping portions where each gripping portion is intended for gripping of an active element to be transferred and comprises at least one housing opening outwardly through an opening, the housing of each gripping portion being delimited in a material having an ability to occupy a first state when a physical parameter associated to said material takes on a value comprised within a first range of values and a second state when the value taken on by the physical parameter is comprised within a second range of values, the second range of values being separate from the first range of values, said material having a greater ability to deform in the first state than in the second state;
the transfer device being adapted to be used in a manufacturing method according to claim 1 to transfer at least one of said active elements towards a receiving substrate belonging to the electronic device from a primary substrate having a support face on which the least one active element to be transferred is disposed.
